(19) United States
(12) Patent Application Publication
(10) Pub. No.: US 2019/0157622 A1
(43) Pub. Date: May 23, 2019

(54) OPTICAL DEVICE, LIGHT EMITTING DEVICE, OPTICAL APPARATUS UTILIZING SAME, AND PRODUCTION METHOD THEREOF

(71) Applicant: SCIVAX CORPORATION, Kanagawa (JP)

(72) Inventors: Akifumi Nawata, Kanagawa (JP); Nobuyoshi Awaya, Kanagawa (JP); Yoshikane Tanaami, Kanagawa (JP); Satoru Tanaka, Kanagawa (JP)

(21) Appl. No.: 16/317,598

(22) PCT Filed: Jul. 12, 2017
(86) PCT No.: PCT/JP2017/025375

§ 371 Date: Jan. 14, 2019

(30) Foreign Application Priority Data
Jul. 13, 2016 (JP) 2016-138886

(51) Int. Cl. H01L 51/52; H01L 33/32; H01L 33/60; G02B 5/30

(52) U.S. Cl. CPC H01L 51/5281; G02B 5/3025; H01L 33/60; H01L 33/32

(57) ABSTRACT

An optical element which is capable of improving the degree of transmission of electromagnetic waves, and which does not require positioning; a light emitting element; an optical device which uses this light emitting element; and a method for producing this optical element. An optical element for controlling the optical characteristics of electromagnetic waves having a wavelength λ, which is provided with: a polarizer part that is composed of a recessed and projected structure and transmits P-polarized light of incident electromagnetic waves, while reflecting S-polarized light of the incident electromagnetic waves; a first retardation element part that is composed of a recessed and projected structure and is capable of converting linearly polarized light to circularly polarized light or elliptically polarized light; and a base part on which the polarizer part and the first retardation element part are formed, and which is capable of transmitting electromagnetic waves between the polarizer part and the first retardation element part.

### TECHNICAL FIELD

The present disclosure relates to an optical device, a light emitting device, an optical apparatus that utilizes the optical device and the light emitting device, and a production method thereof.

### BACKGROUND ART

Conventionally, in order to control the optical characteristics of electromagnetic waves, a polarizer and a phase difference element are utilized. For example, a wire grid polarizer has advantages such that it has a high heat resistance, a high anti-environment characteristic, a high transmissivity that does not have an absorption of P polarized light, a functionality within a broad wavelength band, a high color reproducibility, and a capability of thinning, etc., and is applied as a polarizer for a liquid crystal display, a polarization lighting for photolithography, a UV polarization lighting for light orientation, etc.

### CITATION LIST

### Patent Literatures

Patent Document 1: JP 2008-268295 A

### SUMMARY OF INVENTION

### Technical Problem

Such a wire grid polarizer can increase a transmissivity efficiency when reflected S polarized light is re-utilizable. However, since the direction of polarization does not change if the reflected S polarized light is simply reflected by the opposing mirror, such a reflected light cannot be caused to pass through the wire grid polarizer.

Moreover, although the optical characteristics of electromagnetic waves are controllable by a combination of the polarizer and the phase difference element, and in this case, positioning of the direction of the polarizer and that of the phase difference element are cumbersome.

Accordingly, an objective of the present disclosure is to provide an optical device, a light emitting device, an optical apparatus utilizing those, and a production method thereof which can improve the transmissivity for electromagnetic waves, and which do not need positioning.

### Solution to Problem

In order to accomplish the above objective, an optical device according to the present disclosure controls an optical characteristic of an electromagnetic wave with a wavelength λ, and includes: a polarizer which includes a concavo-convex structure, allows a P polarized light of the incident electromagnetic wave to pass through, and reflects an S polarized light thereof;

a first phase difference element which includes a concavo-convex structure, and which is capable of converting a linear polarized light into a circular polarized light or an elliptical polarized light; and

a base on which the polarizer and the first phase difference element are formed, and which is transmissive for the electromagnetic wave between the polarizer and the first phase difference element.

In this case, the optical device may further include a protector that protects either one of or both of the polarizer and the first phase difference element.

The first phase difference element may be formed of an inorganic compound. Moreover, the first phase difference element may be formed of a same material as the base, and be formed integrally therewith.

Furthermore, the first phase difference element may be formed of a metal or of a metal oxide. In this case, it is preferable that the first phase difference element should have an ellipticity of the electromagnetic wave that is equal to or greater than 0.7 when the electromagnetic wave having undergone linear polarization is caused to pass through. Moreover, it is preferable that a pitch of the concavo-convex structure of the first phase difference element should be formed so as to be equal to or smaller than λ. Furthermore, it is preferable that a pitch of the concavo-convex structure of the first phase difference element should be formed so as to be equal to or greater than 0.35λ.

In addition, it is preferable that the polarizer should be formed of a material that has electrons excited by the electromagnetic wave with the wavelength λ, and the first phase difference element should be formed of a material that has electrons not excited by the electromagnetic wave with the wavelength λ.

The concavo-convex structure of the first phase difference element may be formed in a line-and-space shape that has a smaller width than the wavelength λ.

Depending on the application, the optical device may further include a second phase difference element capable of converting a linear polarized light that has passed through the polarizer or a linear polarized light reflected by the polarizer into a circular polarized light or an elliptical polarized light. In this case, at least either one of the first phase difference element or the second phase difference element is capable of converting the electromagnetic wave that has passed through the polarizer into a right circular polarized light or a right elliptical polarized light, or, into a left circular polarized light or a left elliptical polarized light.

Another optical device according to the present disclosure controls an optical characteristic of an electromagnetic wave with a wavelength λ, and includes:

a polarizer which includes a concavo-convex structure, allows a P polarized light of the incident electromagnetic wave to pass through, and absorbs an S polarized light thereof;

a first phase difference element which includes a concavo-convex structure, and which is capable of converting a linear polarized light into a circular polarized light or an elliptical polarized light; and

a base on which the polarizer and the first phase difference element are formed, and which is transmissive for the electromagnetic wave between the polarizer and the first phase difference element.

A light emitting device according to the present disclosure includes a light emitting layer that emits an electromagnetic wave with a wavelength λ, and includes:

a polarizer which includes a concavo-convex structure, allows a P polarized light of the incident electromagnetic wave to pass through, and reflects an S polarized light thereof;

a mirror which is provided at an opposite side of the polarizer to the light emitting layer, and which reflects the electromagnetic wave toward the polarizer; and

a first phase difference element which includes a concavo-convex structure, and which is capable of converting the reflected electromagnetic wave by the polarizer into a circular polarized light or an elliptical polarized light.

In this case, the light emitting device may further include a protector that protects the polarizer.

Moreover, the first phase difference element may be formed of an inorganic compound.

Furthermore, the first phase difference element may be formed of a metal or of a metal oxide. In this case, it is preferable that the first phase difference element should have an ellipticity of the electromagnetic wave that is equal to or greater than 0.7 when the electromagnetic wave having undergone linear polarization is caused to pass through. Moreover, it is preferable that a pitch of the concavo-convex structure of the first phase difference element should be formed so as to be equal to or smaller than λ. Furthermore, it is preferable that a pitch of the concavo-convex structure of the first phase difference element should be formed so as to be equal to or greater than 0.35λ.

Moreover, it is preferable that the polarizer should be formed of a material that has electrons excited by the electromagnetic wave with the wavelength λ, and the first phase difference element should be formed of a material that has electrons not excited by the electromagnetic wave with the wavelength λ.

Depending on the application, the light emitting device may further include a second phase difference element capable of converting a linear polarized light that has passed through the polarizer into a circular polarized light or an elliptical polarized light. In this case, at least either one of the first phase difference element or the second phase difference element is capable of converting the electromagnetic wave that has passed through the polarizer into a right circular polarized light or a right elliptical polarized light, or, into a left circular polarized light or a left elliptical polarized light.

Moreover, it is preferable that the mirror should be placed so as to be apart from the first phase difference element.

The first phase difference element includes the concavo-convex structure that is formed in a line-and-space shape that has a smaller width than the wavelength λ.

An optical apparatus according to the present disclosure includes:

a light emitting device that emits an electromagnetic wave with a wavelength λ;

the optical device capable of controlling the electromagnetic wave according to any one of claims 1 to 14; and p a mirror which is placed at an opposite side of the optical device to the light emitting device, and which reflects the electromagnetic wave toward the optical device.

Another optical apparatus according to the present disclosure includes:

the above-described light emitting device of the present disclosure; and

a phase difference element capable of converting the electromagnetic wave emitted by the light emitting device into a circular polarized light or an elliptical polarized light.

In this case, the phase difference element is capable of converting the electromagnetic wave emitted by the light emitting device into a right circular polarized light or a right elliptical polarized light, or, into a left circular polarized light or a left elliptical polarized light.

A production method according to the present disclosure is of an optical device that includes a polarizer which includes a concavo-convex structure, allows a P polarized light of an incident electromagnetic wave to pass through, and reflects an S polarized light thereof, and a first phase difference element which includes a concavo-convex structure, and which is capable of converting a linear polarized light into a circular polarized light or an elliptical polarized light, and the method includes:

a first phase difference element forming process to form the first phase difference element;

a protector forming process to form a protector that protects the concavo-convex structure of the first phase difference element; and

a polarizer forming process to form the polarizer.

Another production method according to the present disclosure is of an optical device including a polarizer which includes a concavo-convex structure, allows a P polarized light of an incident electromagnetic wave to pass through, and reflects an S polarized light thereof, and a first phase difference element which includes a concavo-convex structure, and which is capable of converting a linear polarized light into a circular polarized light or an elliptical polarized light, and the method includes:

a polarizer forming process to form the polarizer;

a protector forming process to form a protector that protects the concavo-convex structure of the polarizer; and

a first phase difference element forming process to form the first phase difference element.

The other production method according to the present disclosure is of an optical device including a polarizer which includes a concavo-convex structure, allows a P polarized light of an incident electromagnetic wave to pass through, and reflects an S polarized light thereof, and a first phase difference element which includes a concavo-convex structure, and which is capable of converting a linear polarized light into a circular polarized light or an elliptical polarized light, and the method includes:

a first phase difference element forming process to form the first phase difference element;

a polarizer forming process to form the polarizer; and

a first joining process to join the first phase difference element and the polarizer together.

In those cases, the method may further include:

a second phase difference element forming process to form a second phase difference element capable of converting a linear polarized light into a circular polarized light or an elliptical polarized light; and

a second joining process to join the second phase difference element and the polarizer together.

### Advantageous Effects of Invention

According to the optical element, the light emitting element, and the optical apparatus utilizing the same are capable of efficiently taking out electromagnetic waves. Moreover, alignment of the polarizer and that of the phase difference element become unnecessary.

### BRIEF DESCRIPTION OF DRAWINGS

FIG. 1 is a schematic perspective view illustrating an optical device according to the present disclosure from a polarizer side;

FIG. 2 is a schematic perspective view illustrating the optical device according to the present disclosure from a first-phase-difference-element side;

FIG. 3 is a schematic cross-sectional view illustrating the optical device according to the present disclosure;

FIG. 4 is a schematic cross-sectional view illustrating the optical device provided with a protector according to the present disclosure;

FIG. 5 is a schematic cross-sectional view illustrating a production method of the optical device according to the present disclosure;

FIG. 6 is a schematic cross-sectional view illustrating another production method of the optical device according to the present disclosure;

FIG. 7 is a schematic cross-sectional view illustrating the other production method of the optical device according to the present disclosure;

FIG. 8 is a schematic cross-sectional view illustrating an optical apparatus according to the present disclosure;

FIG. 9 is a schematic cross-sectional view illustrating a light emitting device according to the present disclosure; and

FIG. 10 is a schematic cross-sectional view illustrating another light emitting device according to the present disclosure.

### DESCRIPTION OF EMBODIMENTS

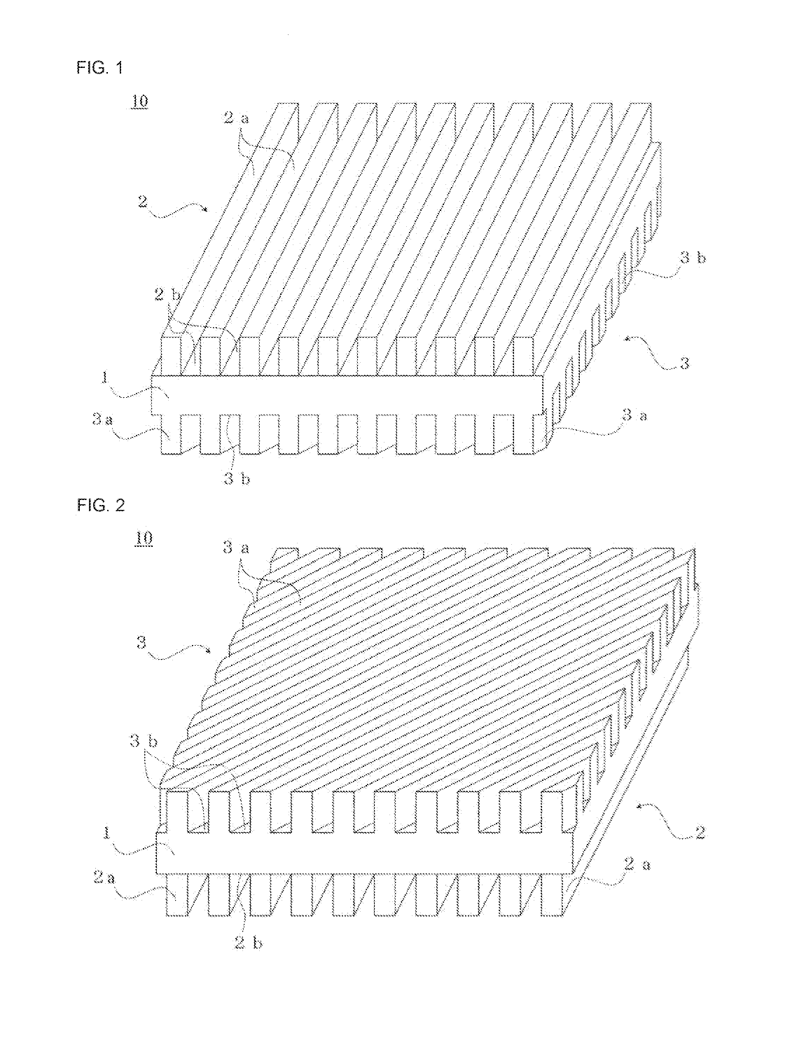

An optical device 10 according to the present disclosure will be described below. As illustrated in FIG. 1 to FIG. 4, the optical device 10 according to the present disclosure is to control the optical characteristics of electromagnetic waves with a wavelength λ, and mainly includes a base 1, a polarizer 2, and a first phase difference element 3 both formed on the base 1.

Note that the wavelength λ means a wavelength in a vacuum. Moreover, the magnitude of the wavelength λ may have a certain range.

The base 1 is formed of a dielectric which supports the polarizer 2 and the first phase difference element 3, and which is transmissive for electromagnetic waves between the polarizer 2 and the first phase difference element 3. The dielectric is not limited to any particular one as long as it can cause desired electromagnetic waves to be transmissive, but for example, inorganic compounds, such as quartz and non-alkali glass, are applicable. Moreover, a resin is applicable. The shape of the base 1 is not limited to any particular shape as long as it can guide the electromagnetic waves that has passed through the first phase difference element 3 to the polarizer 2, or the electromagnetic waves that has passed through the polarizer 2 to the first phase difference element 3, and for example, as illustrated in FIG. 1 to FIG. 4, the base is formed in a substrate shape that has a first surface and a second surface parallel to each other.

The polarizer 2 employs a concavo-convex structure formed on the base 1, allows the P polarized light of the incident electromagnetic waves to pass through and S polarized light to be reflected. In this case, the P polarized light means polarized light of a perpendicular electric field to a predefined reference direction, and the S polarized light means polarized light of the parallel electric field to the reference direction. A conventionally known polarizer 2 like a wire grid is applicable. For example, a plurality of metal lines (convexities 2a) formed so as to be in parallel with each other in a line-and-space shape on one surface of the base 1 is applicable. In this case, the P polarized light means polarized light of the perpendicular electric field to the lines of the convexities 2a, and the S polarized light means polarized light of the parallel electric field to the lines of the convexities 2a.

The convexities 2a may employ a multi-layer structure formed of a plurality of materials. Moreover, regarding the polarizer 2, the narrower the pitch of the concavo-convex structure is, and the higher the aspect ratio is, the higher the extinction ratio is obtained across a broad wavelength band, in particular, a short wavelength band, thus preferable. In the case of, for example, a liquid crystal display, an excellent extinction ratio is necessary within a visible range with a wavelength of 380 to 800 nm, and it is preferable that the pitch of the concavo-convex structure should be 50 nm to 300 nm, the width of the convexity 2a should be 25 nm to 200 nm, and the aspect ratio of the convexity 2a should be equal to or greater than 1. Moreover, a preferable material applied for the convexities 2a of the concavo-convex structure is one that has electrons to be excited by the electromagnetic waves with the wavelength λ. For example, a metal or a metal oxide that has a small bandgap, and more specifically, chrome oxide (Cr₂O₃), tantalum pentoxide (Ta₂O₅), titanium oxide (TiO₂), etc., are applicable.

Note that the polarizer 2 may have the dielectric of the base 1 filled between (concavity 2b) the metal lines (convexities 2a). This enhances the rigidity, and suppresses a corrosion of a metal part. Moreover, depending on an application, as the polarizer 2, one which allows the P polarized light of the incident electromagnetic waves to pass through, and which absorbs the S polarized light may be applied.

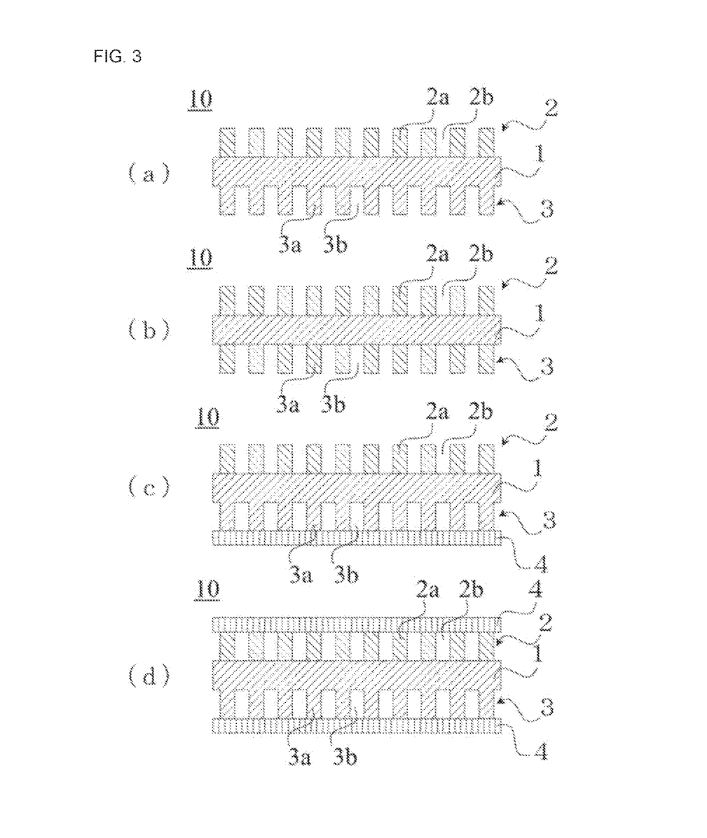

The first phase difference element 3 employs a concavo-convex structure formed on the base 1, and is capable of converting linear polarized light into circular polarized light or elliptical polarized light. It is preferable that an ellipticity after the conversion should be equal to or higher than 0.6, and more preferably, equal to or higher than 0.7. The concavo-convex structure is not limited to any particular one as long as it can give a phase difference to the electromagnetic waves that has passed through such a structure, but may be formed in a line-and-space shape that has convexities 3a and concavities 3b with a smaller width than the wavelength λ. Moreover, as illustrated in FIG. 3A, the concavo-convex structure may be formed of the same material as that of the base 1 and may be formed integrally therewith, or as illustrated in FIG. 3B, may be formed of a different material from that of the base 1. Example materials applicable to the convexities 3a of the concavo-convex structure are inorganic compounds, such as quartz and non-alkali glass, metals, such as silver, gold, aluminum, nickel, and copper, silicon dioxide (SiO₂), and a metal oxide like aluminum oxide (Al₂O₃). Moreover, a resin maybe applied. Furthermore, it is preferable that such a material should not have electrons not excited by the electromagnetic waves with the wavelength λ, silicon dioxide (SiO₂) and a metal oxide like aluminum oxide (Al₂O₃) correspond to such material.

Next, an example case in which the concavo-convex structure is formed of a different material from that of the base 1, and the first phase difference element 3 which is formed of a plurality of metal structures (convexities 3a) is formed on the base 1 that is formed of a dielectric will be described. As illustrated in FIG. 3B, the concavo-convex structure of the first phase difference element 3 is in the line-and-space shape having a plurality of linear metal structures (convexities 3a) arranged in parallel to each other at a uniform pitch. The metal structure is formed so as to have a smaller width than the wavelength λ of the electromagnetic waves. Moreover, regarding the cross-section of the metal structure, it is preferable that, when the electromagnetic waves that are linear polarized lights with a predetermined wavelength enter so as to have a polarization direction that has an angle of 45 degrees relative to the linear direction of the metal structure, the absolute value of the ellipticity of the transmitting wave should become equal to or higher than 0.7. The term ellipticity means, when the trajectory of the electromagnetic waves is projected on a perpendicular plane to the traveling direction of the electromagnetic waves, a ratio b/a where a is the length of the longer axis of an ellipse and b is the length of the short axis thereof. When the absolute value of this ellipticity is equal to or higher than 0.7, the transmitting wave can be regarded as a circular polarized light within 3 dB. Example specific cross-sections are a rectangular shape, a triangular shape, and a trapezoidal shape.

Example metals applicable are silver, gold, aluminum, nickel, and copper, etc., but the present disclosure is not limited to these metals.

A phase difference can be given to the electromagnetic waves when the electromagnetic waves are caused to pass through between the metal structures formed as described above.

Moreover, regarding the pitch P between the metal structures, it is preferable that, when the electromagnetic waves that are linear polarized lights enter so as to have a polarization direction that has an angle of 45 degrees relative to the linear direction of the metal structure, the absolute value of the ellipticity of the transmitting wave should be equal to or higher than 0.7.

Moreover, regarding the width and height of the metal structure, also, it is preferable that, when the electromagnetic waves that are linear polarized lights enter so as to have a polarization direction that has an angle of 45 degrees relative to the linear direction of the metal structure, the absolute value of the ellipticity of the transmitting wave should be equal to or higher than 0.7. Note that the transmissivity for the electromagnetic waves is adjustable by the width and height of the metal structure.

Moreover, the first phase difference element 3 may have the dielectric of the base 1 filled between (concavity) the metal structures (convexities). This enhances the rigidity, and suppress a corrosion of the metal part.

Furthermore, as illustrated in FIGS. 3C and 3D, the polarizer 2 and the first phase difference element 3 may have respective protectors 4 which cover the surfaces thereof and which protect the respective concavo-convex structures. This prevents or suppresses the concavo-convex structure of the polarizer 2 and that of the first phase difference element 3 from being damaged or polluted at the time of production and use. A material of the protector is not limited to any material as long as the desired electromagnetic waves are transmissive, but for example, inorganic compounds, such as quartz and non-alkali glass, are applicable. Moreover, a resin is also applicable.

Moreover, when the protector 4 is formed, it is preferable to form a clearance between the convexities 2a of the concavo-convex structure of the polarizer 2. This holds a gas like air that has a dielectric constant close to 1 between the convexities 2a, in comparison with a case in which the space between the convexities 2a is filled by the material of the protector 4, the light transmissivity in the polarizer 2 can be improved. It is sufficient if such a clearance is filled by a gas like air. Moreover, such a clearance may be vacuumed.

Moreover, the growth of plant lives largely varies depending on the quality of light, and it is conventionally known that, when, for example, a right circular polarized light is emitted for cultivation, the growth is promoted, and when a left circular polarized light is emitted for cultivation, the growth is suppressed. Hence, a second phase difference element 5 may be further provided which is capable of converting linear polarized light passing through the polarizer 2 or linear polarized light reflected by the polarizer 2 into circular polarized light or elliptical polarized light. This enables at least either one of the first phase difference element 3 and the second phase difference element 5 to convert the electromagnetic waves that has passed through the polarizer 2 into right circular polarized light or right elliptical polarized light, or, left circular polarized light or left elliptical polarized light.

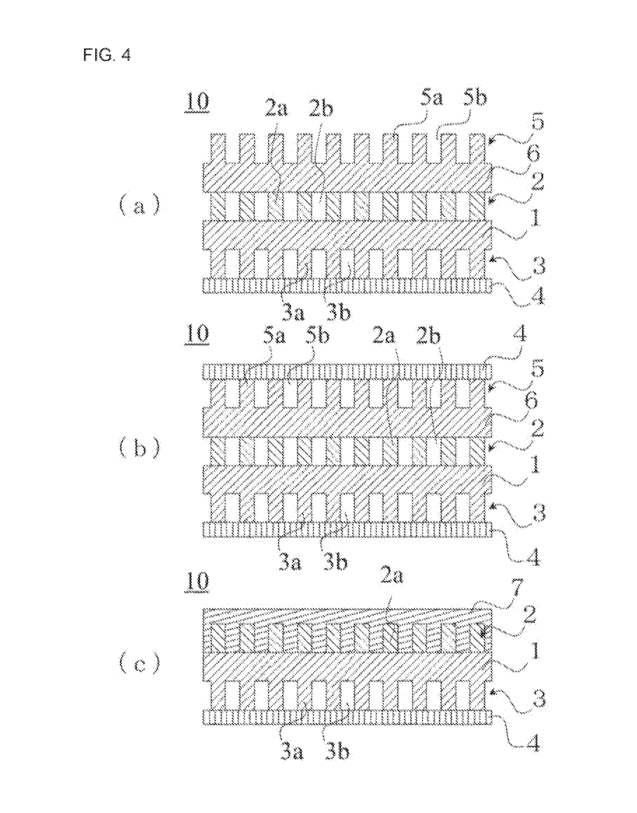

As illustrated in FIG. 4A, the second phase difference element 5 is provided with a second base 6 on the polarizer 2 so as to support the second phase difference element 5, and the same concavo-convex structure as that of the first phase difference element 3 as described above maybe formed on the base 6. The base 6 is formed of a dielectric that is transmissive for the electromagnetic waves. The dielectric is not limited to any particular dielectric as long as the desired electromagnetic waves are transmissive, but for example, inorganic compounds, such as quartz and non-alkali glass, are applicable. Moreover, a resin is also applicable. As long as it can guide the electromagnetic waves that has passed through the second phase difference element 5 to the polarizer 2 or the electromagnetic waves that has passed through the polarizer 2 to the second phase difference element 5, the shape of the base 6 is not limited to any particular shape, but for example, is formed in a substrate shape that has a first surface and a second surface parallel to each other. Note that the base 6 also functions as a protector which covers the surface of the polarizer 2 and which protects the concavo-convex structure of the polarizer 2. Moreover, as illustrated in FIG. 4B, the protector 4 maybe provided which covers the surface of the second phase difference element 5 and which protects the concavo-convex structure of the second phase difference element 5.

Moreover, as another form of the second phase difference element 5, as illustrated in FIG. 4C, a phase difference film 7 that utilizes birefringence caused by the orientation of macromolecules due to elongation may be placed on the concavo-convex structure of the polarizer 2.

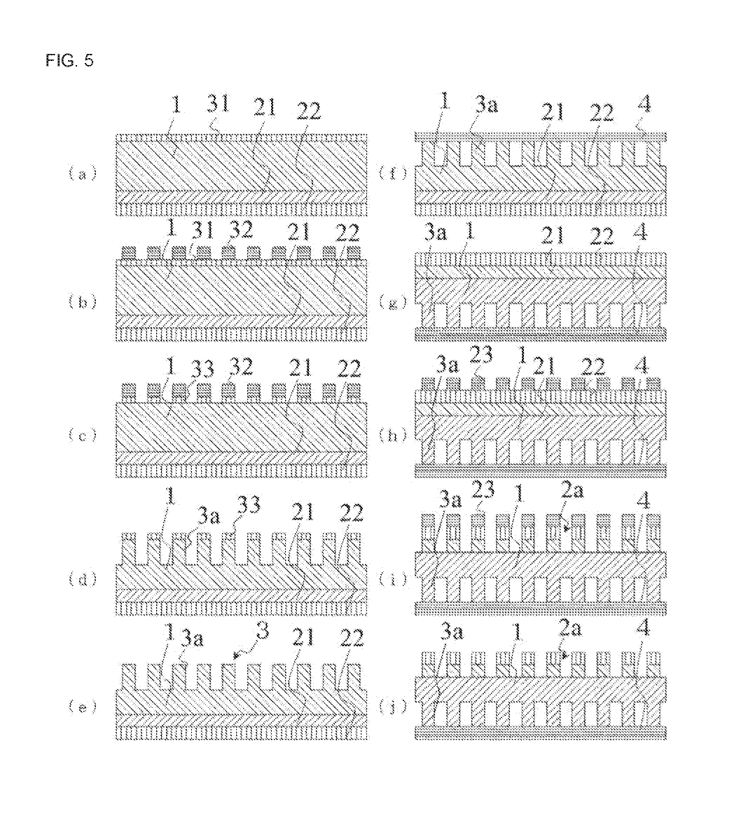

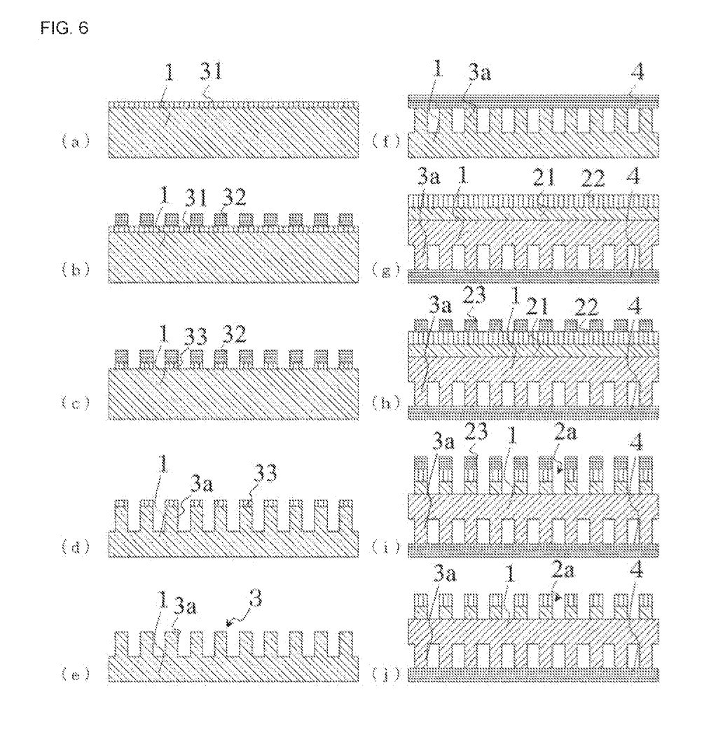

Next, a production method of the optical device according to the present disclosure as described above will be described. As illustrated in FIGS. 5A to 5J or FIG. 6A to 6J, a first production method of the optical device according to the present disclosure mainly contains a first phase difference element forming process to form the first phase difference element 3, a protector forming process to form the protector 4 that protects the surface of the first phase difference element 3, and a polarizer forming process to form the polarizer 2.

The first phase difference element forming process is to form the first phase difference element 3 of the present disclosure as described above. Conventionally known schemes are applicable as long as the first phase difference element 3 can be formed. For example, this process contains a mask pattern forming process to form a mask pattern for forming the concavo-convex structure of the first phase difference element 3 on the base 1 like a glass, and a concavo-convex structure forming process to form the concavo-convex structure of the first phase difference element 3 on the base 1 in accordance with the mask pattern.

For example, the mask pattern forming process may contain, as illustrated in FIGS. 5A and 6A, a metal film forming process to form a metal film 31 like chromium on the bases 1 like glass, an unillustrated resist film forming process to apply a resist on the surface of the metal film 31, as illustrated in FIGS. 5B and 6B, a resist pattern forming process to forma resist pattern 32 for forming the concavo-convex structure of the first phase difference element 3 on the resist film by imprinting, photolithography, etc., and as illustrated in FIGS. 5C and 6C, a metal pattern forming process to form a metal pattern 33 (mask pattern) in the metal film 31 based on the resist pattern 32.

In the concavo-convex structure forming process, as illustrated in FIGS. 5D and 6D, etching is performed on the base 1 using the mask pattern as a mask, and as illustrated in FIGS. 5E and 6E, the remaining metal pattern 33 is eliminated so as to form the concavo-convex structure that has the convexities 3a on the base 1.

The protector forming process is, as illustrated in FIGS. 5F and 6F, to form the protector 4 that protects the concavo-convex structure of the first phase difference element 3 formed through the first phase difference element forming process. As for the protector 4, a film formed of, for example, silicon dioxide (SiO₂) maybe formed on the surface of concavo-convex structure. Hence, as illustrated in FIG. 5G and FIG. 6G, the first phase difference element may be faced down in the polarizer forming process to form the polarizer 2, a damage, etc., to the concavo-convex structure of the first phase difference element 3 can be prevented or suppressed. As for the formation of the film formed of silicon dioxide (SiO₂), conventionally known schemes are applicable, and for example, electron beam vapor deposition may be applied. Note that when it is desirable to form a gap between the convexities 2a of the concavo-convex structure, it is preferable that a film formation scheme that has a low coatability for unevenness, such as sputtering or vapor deposition, and the gap should be formed between the convexities 2a of the concavo-convex structure.

The polarizer forming process is to form the polarizer 2 of the present disclosure as described above. Conventionally known schemes are applicable as long as the polarizer 2 can be formed. For example, this process may contain a polarizer material film forming process to form the film of the material for the polarizer 2, a mask pattern forming process to form a mask pattern for forming the concavo-convex structure of the polarizer 2 on the film, and a concavo-convex structure forming process to form the concavo-convex structure of the polarizer 2 on the film in accordance with the mask pattern.

In the polarizer material film forming process, for example, as illustrated in FIG. 5A, a metal film 21 like aluminum may be formed on the bases 1 like a glass, and a film 22 formed of silicon dioxide (SiO₂) may be formed on the surface. Note that, as illustrated in FIG. 6G, the polarizer material film forming process may be executed after the first phase difference element 3 is formed.

The mask pattern forming process may contain, for example, a resist applying process (unillustrated) to apply a resist on the surface of the film 22, and as illustrated in FIG. 5H and FIG. 6H, a resist pattern forming process to form a resist pattern 23 for forming the concavo-convex structure of a polarizer in the resist film by imprinting, photolithography, etc.

In the concavo-convex structure forming process, as illustrated in FIG. 5I and FIG. 6I, etching is performed on the film 22 that includes the metal film 21 and silicon dioxide (SiO₂) with the resist pattern 23 being as a mask, and as illustrated in FIG. 5J and FIG. 6J, the remaining resist is eliminated to form the concavo-convex structure that has the convexities 2a on the base 1.

Note that in the above description, although the description has been given of an example case in which the first phase difference element 3 is formed and then the polarizer 2 is formed, needless to say, it is also possible to form the polarizer 2 and then form the first phase difference element 3. In this case, in order to protect the concavo-convex structure of the polarizer 2, the protector 4 may be formed on the surface of the concavo-convex structure of the polarizer 2.

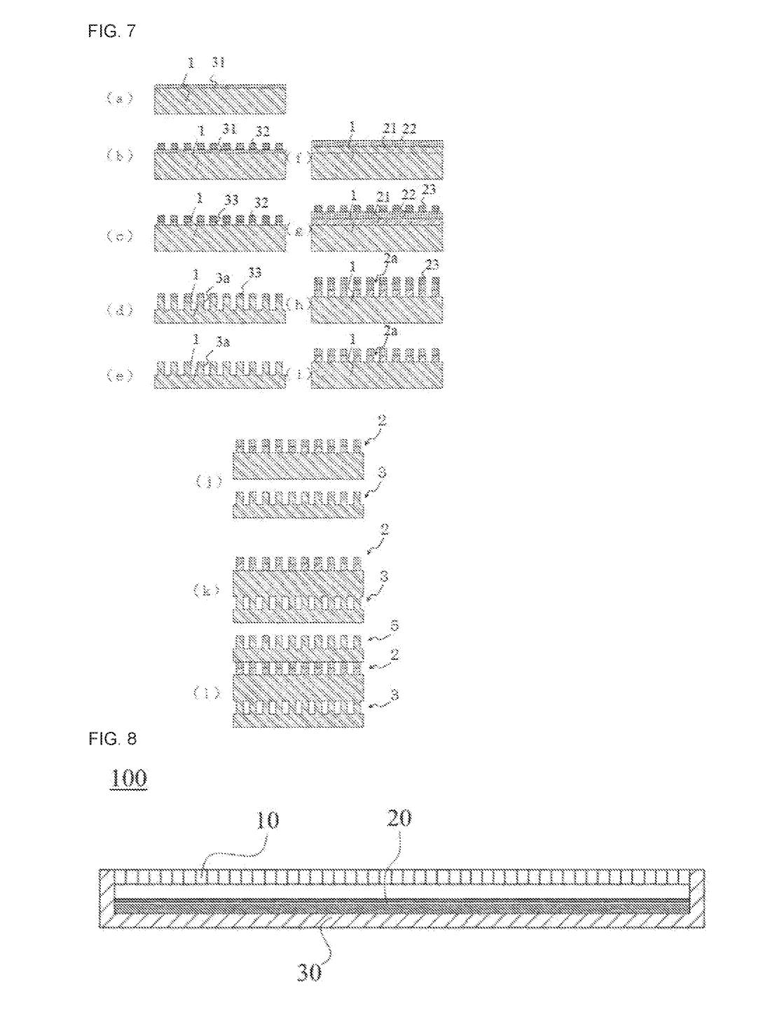

Moreover, a second production method of the optical device according to the present disclosure is to create the first phase difference element 3 and the polarizer 2 separately from each other, and then join those together. More specifically, as illustrated in FIGS. 7A to 7E, this method mainly contains a first phase difference element forming process to form the first phase difference element 3, as illustrated in FIGS. 7F to 7I, a polarizer forming process to form the polarizer 2, and as illustrated in FIGS. 7J and 7K, a first joining process to join the first phase difference element 3 and the polarizer 2 together.

Note that since the first phase difference element forming process and the polarizer forming process are the same as the first phase difference element forming process of the above-described first production method and the polarizer forming process thereof, the same reference numeral will be given to the same component, and the duplicated description will be omitted.

As for the first joining process, a conventionally known scheme is applicable as long as the first phase difference element 3 and the polarizer 2 can be joined together. For example, the first phase difference element 3 and the polarizer 2 may be pasted together by an adhesive etc.

Note that the above-described first production method or second production method of the optical device may further contain a second phase difference element forming process to form the second phase difference element 5 that is capable of converting linear polarized light into circular polarized light or elliptical polarized light, and a second joining process to join the second phase difference element 5 and the polarizer 2 together. The formation method of the second phase difference element can be performed like the formation of the above-described first phase difference element 3. As for the second joining process, a conventionally known scheme is applicable as long as the second phase difference element 5 and the polarizer 2 can be joined together. For example, as illustrated in FIG. 7I, the second phase difference element 5 and the polarizer 2 maybe pasted together by an adhesive, etc.

Next, an optical apparatus 100 that utilizes the optical device 10 which employs the structure as described above will be described with reference to FIG. 8. The optical apparatus 100 according to the present disclosure mainly includes the optical device 10 of the present disclosure as described above, a light emitting device 20, and a mirror 30.

The light emitting device 20 is not limited to any particular one as long as it can emit the electromagnetic waves with the wavelength λ, but for example, a light emitting diode (LED), an organic electroluminescence (OEL), etc., are applicable. Note that the magnitude of the wavelength λ may have a certain range.

The mirror 30 is placed at the opposite side of the optical device 10 to the light emitting device 20, and reflects the electromagnetic waves toward the optical device 10. The mirror 30 is not limited to any particular one as long as it can reflect the electromagnetic waves toward the optical device 10, and a conventionally known one may be applied.

The principle of the optical apparatus 100 according to the present disclosure will be described below.

Regarding the electromagnetic waves emitted from the light emitting device 20, the P wave passes through the polarizer 2 of the optical device 10, but the S wave is reflected. The reflected electromagnetic waves are converted into the circular polarized light (or elliptical polarized light) by the first phase difference element 3. Next, when the electromagnetic waves are reflected by the mirror 30, it become the circular polarized light (or elliptical polarized light) in the reverse turn to the direction of turn prior to the reflection. When such electromagnetic waves pass through the first phase difference element 3 again, the linear polarized light that has a different angle from that of the S wave. Regarding such electromagnetic waves, the P wave passes through the polarizer 2 again, but the S wave is reflected. By repeating these actions, the electromagnetic waves emitted from the light emitting device 20 can be efficiently taken out as the P wave. When, in particular, the phase difference given by the first phase difference element 3 is ¼ wavelength, since most of the electromagnetic waves can be converted into the P wave by single reflection by the mirror and pass through the polarizer 2, the loss by absorption can be minimized.

In this case, however, the aspect ratio of the concavo-convex structure of the first phase difference element 3 is relatively large, and the difficulty for fabrication increases. Accordingly, the phase difference given by the first phase difference element 3 may be ¼n wavelength (where n is a natural number that is equal to or greater than 2). In this case, in order to convert the electromagnetic waves into the P wave, n times of reflections by the mirror 30 is necessary, but the aspect ratio of the concavo-convex structure of the first phase difference element 3 can be made small to 1/n in comparison with the concavo-convex structure that gives the phase difference which is ¼ wavelength, thus facilitating the fabrication. When, for example, the phase difference given by the first phase difference element 3 is ⅛ wavelength, two times of reflections by the mirror 30 are necessary, but the aspect ratio of the concavo-convex structure of the first phase difference element 3 can be half in comparison with the concavo-convex structure that gives the phase difference which is ¼ wavelength. It is preferable that the error in phase difference given by the first phase difference element 3 should be equal to or smaller than ±10% relative to the ¼ wavelength or the ¼n wavelength, and more preferably, be equal to or smaller than 5%.

Note that when the optical device 10 includes the second phase difference element 5, the P wave which has passed through the polarizer 2 is to be converted into the circular polarized light or the elliptical polarized light in the right turn or in the left turn by the second phase difference element 5.

Next, a light emitting device 200 according to the present disclosure will be described. The light emitting device 200 according to the present disclosure has a polarizer 202 and a first phase difference element 203 formed in the structure of the light emitting device 200, and is capable of functioning as the above-described optical apparatus 100 alone. The light emitting device 200 mainly includes a light emitting layer 84 that emits electromagnetic waves with the wavelength λ, the polarizer 202, the first phase difference element 203, and a mirror 90. Note that the magnitude of the wavelength λ of the electromagnetic waves emitted by the light emitting layer 84 may have a certain range.

First, the general structure of the light emitting device 200 will be described. The light emitting device 200 mainly includes a plurality of semiconductor layers 8 including the light emitting layer 94, and a substrate 70.

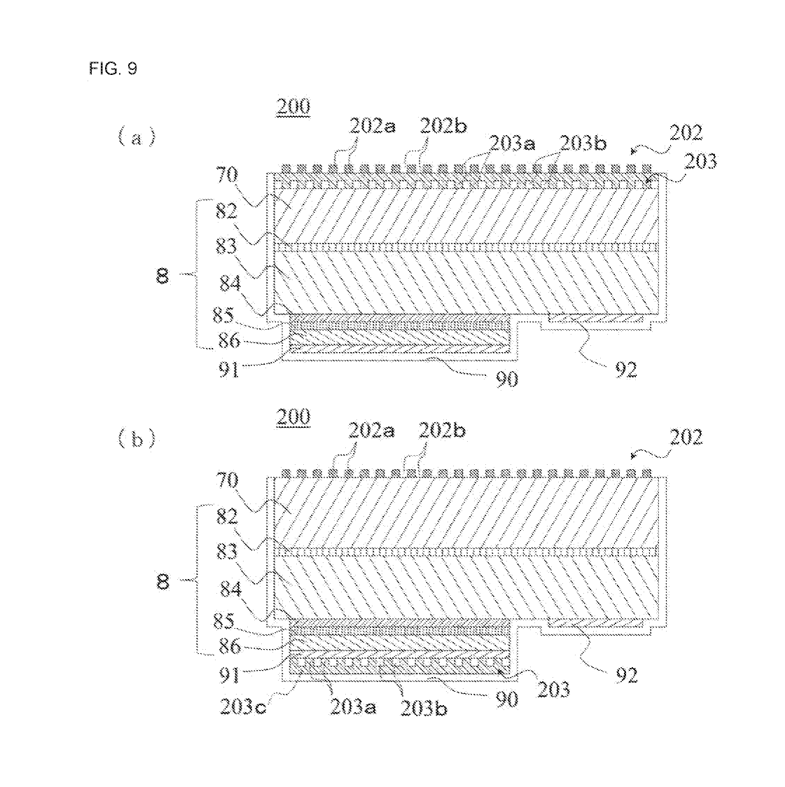

As illustrated in, for example, FIGS. 9A and 9B, the semiconductor layer 8 is formed of a group-III nitride semiconductor layer formed on the sapphire substrate 70. Although the light emitting device 200 illustrated in FIGS. 9A and 9B takes out light from the sapphire-substrate-70 side (light taken side below), the light maybe taken out from the opposite side to the sapphire substrate 70. The group-III nitride semiconductor layer includes, for example, a buffer layer 82, an N-type GaN layer 83, the light emitting layer 84 (multiquantum well active layer), an electron blocking layer 85, and a P-type GaN layer 86, and those are formed in sequence from the sapphire-substrate-70 side. Moreover, a P-electrode 91 is formed on the P-type GaN layer 86, and an N-electrode 92 is formed on the N-type GaN layer 83.

The buffer layer 82 is formed on the sapphire substrate 70, and is formed of AlN. The buffer layer 82 may be formed by Metal Organic Chemical Vapor Deposition (MOCVD) or sputtering. The N-type GaN layer 83 that is a first conduction type layer is formed on the buffer layer 82, and is formed of n-GaN. The light emitting layer 84 (multiquantum well active layer) is formed on the N-type GaN layer 83, and is formed of GaInN/GaN, and emits light by electron or hole injection.

The electron blocking layer 85 is formed on the light emitting layer 84, and is formed of p-AIGaN. The P-type GaN layer 86 that is a second conduction type layer is formed on the electron blocking layer 85, and is formed of p-GaN. The layers from the N-type GaN layer 83 to the P-type GaN layer 86 are formed by epitaxial growth of the group-III nitride semiconductor. Note that the semiconductor layer 8 may employ other structures as long as it includes at least the first conduction type layer, the active layer, and the second conduction type layer, and emits light from the active layer by recombination of electrons and holes when a voltage is applied between the first conduction type layer and the second conduction type layer.

The P-electrode 91 is formed on the P-type GaN layer 86, and is formed of, for example, a transparent material like Indium Tin Oxide (ITO). The P-electrode 91 may be formed by vacuum vapor deposition, sputtering, Chemical Vapor Deposition (CVD), etc.

The N-electrode 92 is formed by performing etching on the N-type GaN layer 83 from the P-type GaN layer 86, and is formed on the exposed N-type GaN layer 83. The N-electrode 92 is formed of, for example, Ti/Al/Ti/Au, and may be formed by vacuum vapor deposition, sputtering, Chemical Vapor Deposition (CVD), etc.

The polarizer 202 includes the concavo-convex structure, allows the P polarized light of the incident electromagnetic waves to pass through, and reflects the S polarized light. The polarizer 202 may be provided at any location as long as the P polarized light of the incident electromagnetic waves can be emitted to the exterior, but for example, as illustrated in FIGS. 9A and 9B, may be placed on the outermost surface (top in the figure) of the light emitting device 200. Regarding the polarizer 202, a conventionally known structure like a wire grid is applicable. For example, a plurality of metal lines (convexities 202a) formed in parallel with each other in a line-and-space shape on the outermost surface of the light emitting device 200 is applicable. Moreover, the convexity 202a may employ a multi-layer structure formed of a plurality of materials. Furthermore, regarding the polarizer 202, the narrower the pitch of the concavo-convex structure is, and the higher the aspect ratio is, the higher the extinction ratio is obtained across a broad wavelength band, in particular, a short wavelength band, thus preferable. In the case of, for example, a liquid crystal display, an excellent extinction ratio is necessary within a visible range with a wavelength of 380 to 800 nm, and it is preferable that the pitch of the concavo-convex structure should be 50 nm to 300 nm, the width of the convexity should be 25 nm to 200 nm, and the aspect ratio of the convexity 2a should be equal to or greater than 1. Moreover, a preferable material applied for the convexities 202a of the concavo-convex structure is one that has electrons to be excited by the electromagnetic waves with the wavelength λ. For example, a metal or a metal oxide that has a small bandgap, and more specifically, chrome oxide (Cr₂O₃), tantalum pentoxide (Ta₂O₅), titanium oxide (TiO₂), etc., are applicable.

The polarizer 202 may be formed on the sapphire substrate 70 by, for example, the same process as the polarizer forming process as described above. Moreover, the polarizer 202 may be formed in advance and then joined to the sapphire substrate 70, etc. Furthermore, the polarizer 202 may include a protector that protects the polarizer when being produced and in use.

Note that the polarizer 202 may have a dielectric filled between (concavity 202b) the metal lines (convexities 202a). This enhances the rigidity, and suppresses a corrosion of a metal part.

The first phase difference element 203 employs a concavo-convex structure, is capable of converting the reflected electromagnetic waves by the polarizer 202 into circular polarized light or elliptical polarized light. As long as it is a location where the reflected magnetic waves by the polarizer 202 can be converted into circular polarized light or elliptical polarized light, the first phase difference element 203 may be provided at any location, but as illustrated in FIG. 9A, for example, it may be placed between the sapphire substrate 70 and the polarizer 202, or as illustrated in FIG. 9B, between the P-electrode 91 and the mirror 90. It is preferable that the ellipticity after conversion by the first phase difference element 203 should be equal to or greater than 0.6, and more preferably, equal to or greater than 0.7. The concavo-convex structure is not limited to any particular one as long as it can give a phase difference to the electromagnetic waves that has passed through such a structure, but for example, may be formed in a line-and-space shape that includes convexities 203a and concavities 203b which have a smaller width than the wavelength λ. Moreover, as illustrated in FIG. 9A, the concavo-convex structure may be formed of the same material as that of a base 203c and be formed integrally therewith, or although it is not illustrated in the figure, may be formed of a different material from that of the base 203c. Furthermore, the base 203c may be omitted. Example materials applicable to the convexities 203a of the concavo-convex structure are inorganic compounds, such as quartz and non-alkali glass, metals, such as silver, gold, aluminum, nickel, and copper, a silicon dioxide (SiO₂), and a metal oxide like aluminum oxide (Al₂O₃). Moreover, a resin may be applied. Furthermore, it is preferable that such a material should have electrons not excited by the electromagnetic waves with the wavelength λ, a silicon dioxide (SiO₂) and a metal oxide like aluminum oxide (Al₂O₃), correspond to such material. A material applied for the concavities 203b of the concavo-convex structure may have a difference in refractive index from at least the material applied for the concavities 203a, and for example, air is applicable.

The first phase difference element 203 may be formed on the sapphire substrate 70 or the P-electrode 91 by, for example, the same process as the first phase difference element forming process as described above. Moreover, the first phase difference element 203 may be formed in advance and then joined to the sapphire substrate 70 or the P-electrode 91.

Next, a description will be given of a case in which the first phase difference element 203 that is formed of a plurality of metal structures (convexities 203a) is formed on the base 203c that is formed of dielectric. The concavo-convex structure of the first phase difference element 203 is in a line-and-space shape having a plurality of linear metal structures (convexities 203a) arranged in parallel to each other at a uniform pitch. The metal structure is formed so as to have a smaller width than the wavelength λ of the electromagnetic waves. Moreover, regarding the cross-section of the metal structure, it is preferable that, when the electromagnetic waves that are linear polarized lights with a predetermined wavelength enter so as to have a polarization direction that has an angle of 45 degrees relative to the linear direction of the metal structure, the absolute value of the ellipticity of the transmitting wave should become equal to or higher than 0.7. Example specific cross-sections are a rectangular shape, a triangular shape, and a trapezoidal shape.

Example metals applicable are silver, gold, aluminum, nickel, and copper, etc., but the present disclosure is not limited to these metals.

A phase difference can be given to the electromagnetic waves when the electromagnetic waves are caused to pass through between the metal structures formed as described above.

Moreover, regarding the pitch P between the metal structures, it is preferable that, when the electromagnetic waves that are linear polarized lights enter so as to have a polarization direction that has an angle of 45 degrees relative to the linear direction of the metal structure, the absolute value of the ellipticity of the transmitting wave should be equal to or higher than 0.7. In this case, the term ellipticity means, when the trajectory of the electromagnetic waves is projected on a perpendicular plane to the traveling direction of the electromagnetic waves, a ratio b/a where a is the length of the longer axis of an ellipse and b is the length of the short axis thereof. When the absolute value of this ellipticity is equal to or higher than 0.7, the transmitting wave can be regarded as a circular polarized light within 3 dB.

Moreover, regarding the width and height of the metal structure, also, it is preferable that, when the electromagnetic waves that are linear polarized lights enter so as to have a polarization direction that has an angle of 45 degrees relative to the linear direction of the metal structure, the absolute value of the ellipticity of the transmitting wave should be equal to or higher than 0.7. Note that the transmissivity for the electromagnetic waves is adjustable by the width and height of the metal structure.

Furthermore, the first phase difference element 203 may have the dielectric of the base 1 filled between (concavity) the metal structures (convexities). This enhances the rigidity, and suppress a corrosion of the metal part.

When the first phase difference element 203 is formed of a plurality of metal structure, if the mirror 90 and the first phase difference element 203 are in contact with each other, the light extraction efficiency decreases. Hence, it is preferable that the mirror 90 should be placed so as to apart from the first phase difference element.

The mirror 90 is provided at the opposite side of the polarizer 202 relative to the light emitting layer 84, and reflects the electromagnetic waves toward the polarizer 202. The mirror 90 may be formed as, for example, as illustrated in FIG. 9A, a reflection film formed of Al, etc., and on the surface (lower side in the figure) the P-electrode 91 or the N-electrode 92. Moreover, as illustrated in FIG. 9B, when the first phase difference element 203 is formed on the surface (lower side in the figure) of the P-electrode 91, the reflection film may be formed on the surface (lower side in the figure) of the first phase difference element 203. Furthermore, the mirror 90 may be formed so as to cover the side face, etc., of the light emitting device 200.

Moreover, as described above, the growth of plant lives largely varies depending on the quality of light, and it is conventionally known that, when, for example, a right circular polarized light is emitted for cultivation, the growth is promoted, and when a left circular polarized light is emitted for cultivation, the growth is suppressed. Hence, the light emitting device 200 according to the present disclosure may further include a second phase difference element 205 which is capable of converting linear polarized light passing through the polarizer 202 and to be emitted to the exterior into circular polarized light or elliptical polarized light. This enables the second phase difference element 205 to convert the electromagnetic waves that has passed through the polarizer 202 into right circular polarized light or right elliptical polarized light, or, left circular polarized light or left elliptical polarized light.

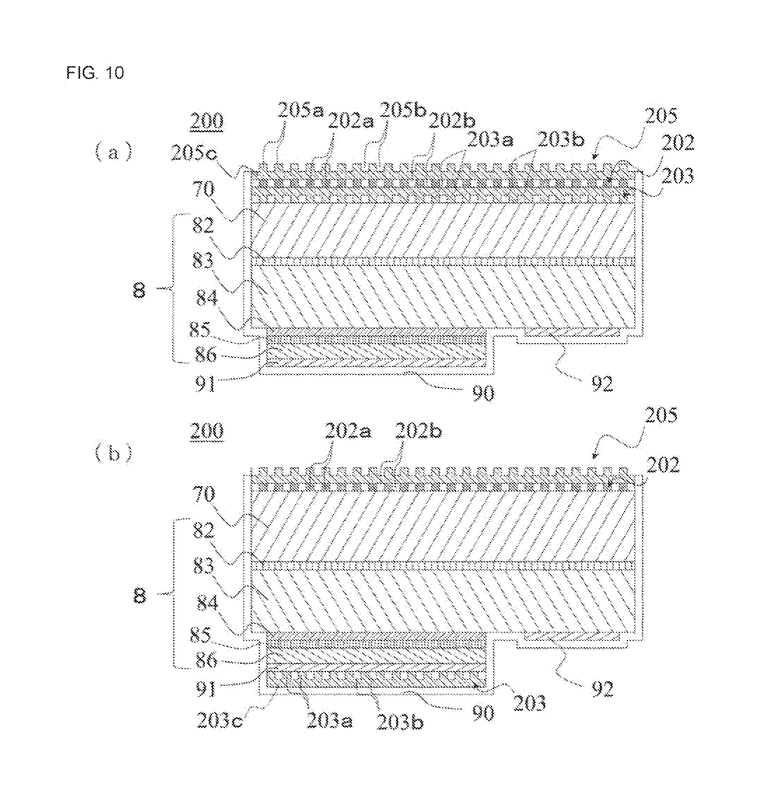

As illustrated in FIGS. 10A and 10B, the second phase difference element 205 is provided with a second base 205c on the polarizer 202 so as to support the second phase difference element 205, and the same concavo-convex structure as that of the first phase difference element 203 as described above may be formed on the base 205c. The base 205c is formed of a dielectric that is transmissive for the electromagnetic waves. The dielectric is not limited to any particular dielectric as long as the desired electromagnetic waves are transmissive, but for example, inorganic compounds, such as quartz and non-alkali glass, are applicable. Moreover, a resin is also applicable. As long as it can guide the electromagnetic waves that has passed through the polarizer 202 to the second phase difference element 205, the shape of the base 205c is not limited to any particular shape, but for example, is formed in a substrate shape that has a first surface and a second surface parallel to each other. Note that the base 205c also functions as a protector which covers the surface of the polarizer 202 and which protects the concavo-convex structure of the polarizer 202. Moreover, although it is not illustrated in the figure, a protector may be further provided which covers the surface of the second phase difference element 205 and which protects the concavo-convex structure of the second phase difference element 205.

Moreover, as another form of the second phase difference element 205, although it is not illustrated in the figure, a phase difference film 7 that utilizes birefringence caused by the orientation of macromolecules due to elongation may be placed on the concavo-convex structure of the polarizer 202. In this case, also, the phase difference film 7 functions as a protector which covers the surface of the polarizer 202 and which protects the concavo-convex structure of the polarizer 202.

Note that the above description has been given of a structure of an LED as the light emitting device 200, the present disclosure is not limited to this case as long as a light emitting layer is provided which emits the electromagnetic waves with the wavelength λ, and for example, the present disclosure is applicable to an organic EL, etc.

Moreover, the light emitting device 200 according to the present disclosure which does not have the second phase difference element and a phase difference element capable of converting the electromagnetic waves emitted from the light emitting device 200 into circular polarized light or elliptical polarized light maybe combined to achieve the optical apparatus. A conventionally known phase difference element is applicable. For example, one that has a concavo-convex structure capable of giving a phase difference to the transmissive electromagnetic waves, or a phase difference film that utilizes birefringence caused by the orientation of macromolecules due to elongation, etc., are applicable.

### REFERENCE SIGNS LIST

1 Base

2 Polarizer

3 First phase difference element

4 Protector

5 Second phase difference element

10 Optical device

20 Light emitting device

30 Mirror

90 Mirror

100 Optical apparatus

200 Light emitting device

202 Polarizer

203 First phase difference element

205 Second phase difference element

What is claimed is:

1. An optical device that controls an optical characteristic of an electromagnetic wave with a wavelength λ, comprising:
a polarizer which comprises a concavo-convex structure, allows a P polarized light of the incident electromagnetic wave to pass through, and reflects an S polarized light thereof;
a first phase difference element which comprises a concavo-convex structure, and which is capable of converting a linear polarized light into a circular polarized light or an elliptical polarized light; and
a base on which the polarizer and the first phase difference element are formed, and which is transmissive for the electromagnetic wave between the polarizer and the first phase difference element.

2. The optical device according to claim 1, further comprising a protector that protects either one of or both of the polarizer and the first phase difference element.

3. The optical device according to claim 1, wherein the first phase difference element is formed of an inorganic compound.

4. The optical device according to claim 1, wherein the first phase difference element is formed of a same material as the base, and is formed integrally therewith.

5. The optical device according to claim 1, wherein the first phase difference element is formed of a metal or of a metal oxide,

6. The optical device according to claim 5, wherein the first phase difference element has an ellipticity of the electromagnetic wave that is equal to or greater than 0.7 when the electromagnetic wave having undergone linear polarization is caused to pass through.

7. The optical device according to claim 5, wherein a pitch of the concavo-convex structure of the first phase difference element is formed so as to be equal to or smaller than λ.

8. The optical device according to claim 5, wherein a pitch of the concavo-convex structure of the first phase difference element is formed so as to be equal to or greater than 0.35λ.

9. The optical device according to claim 1, wherein
the polarizer is formed of a material that has electrons excited by the electromagnetic wave with the wavelength λ; and
the first phase difference element is formed of a material that has electrons not excited by the electromagnetic wave with the wavelength λ.

10. The optical device according to claim 1, wherein the concavo-convex structure of the first phase difference element is formed in a line-and-space shape that has a smaller width than the wavelength λ.

11. The optical device according to claim 1, further comprising a second phase difference element capable of converting a linear polarized light that has passed through the polarizer or a linear polarized light reflected by the polarizer into a circular polarized light or an elliptical polarized light.

12. The optical device according to claim 11, wherein at least either one of the first phase difference element or the second phase difference element is capable of converting the electromagnetic wave that has passed through the polarizer into a right circular polarized light or a right elliptical polarized light.

13. The optical device according to claim 11, wherein at least either one of the first phase difference element or the second phase difference element is capable of converting the electromagnetic wave that has passed through the polarizer into a left circular polarized light or a left elliptical polarized light.

14. An optical device that controls an optical characteristic of an electromagnetic wave with a wavelength λ, comprising:
a polarizer which comprises a concavoconvex structure, allows a P polarized light of the incident electromagnetic wave to pass through, and absorbs an S polarized light thereof;
a first phase difference element which comprises a concavo-convex structure, and which is capable of converting a linear polarized :light into a circular polarized light or an elliptical polarized light; and
a base on which the polarizer and the first phase difference element are formed, and which is transmissive for the electromagnetic wave between the polarizer and the first phase difference element.

15. A light emitting device that comprises a light emitting layer that emits an electromagnetic wave with a wavelength λ, comprising:
a polarizer which comprises a concavo-convex structure, allows a P polarized light of the incident electromagnetic wave to pass through, and reflects an S polarized light thereof;
a mirror which is provided at an opposite side of the polarizer to the light emitting layer, and which reflects the electromagnetic wave toward the polarizer; and
a first phase difference element which comprises a concavo-convex structure, and which is capable of converting the reflected electromagnetic wave by the polarizer into a circular polarized light or an elliptical polarized light.

16. The light emitting device according to claim 15, further comprising a protector that protects the polarizer.

17. The light emitting device according to claim 15, wherein the first phase difference element is formed of an inorganic compound.

18. The light emitting device according to claim 15, wherein the first phase difference element is formed of a metal or of a metal oxide.

19. The light emitting device according to claim 18, wherein the first phase difference element has an ellipticity of the electromagnetic wave that is equal to or greater than 0.7 when the electromagnetic wave having undergone linear polarization is caused to pass through.

20. The light emitting device according to claim 18, wherein a pitch of the concavo-convex structure of the first phase difference element is formed so as to be equal to or smaller than λ.

21. The light emitting device according to claim 18, wherein a pitch of the concavo-convex structure of the first phase difference element is formed so as to be equal to or greater than 0.35λ.

22. The light emitting device according to claim 15, wherein
the polarizer is formed of a material that has electrons excited by the electromagnetic wave with the wavelength λ; and
the first phase difference element is formed of a material that has electrons not excited by the electromagnetic wave with the wavelength λ.

23. The light emitting device according to claim 15, further comprising a second phase difference element capable of converting a linear polarized light that has passed through the polarizer into a circular polarized light or an elliptical polarized light.

24. The light emitting device according to claim 23, wherein at least either one of the first phase difference element or the second phase difference element is capable of converting the electromagnetic wave that has passed through the polarizer into a right circular polarized light or a right elliptical polarized light.

25. The light emitting device according to claim 23, wherein at least either one of the first phase difference element or the second phase difference element is capable of converting the electromagnetic wave that has passed through the polarizer into a left circular polarized light or a left elliptical polarized light.

26. The light emitting device according to claim 15, wherein the mirror is placed so as to be apart from the first phase difference element.

27. The light emitting device according to claim 15, wherein the first phase difference element comprises the concavo-convex structure that is formed in a line-and-space shape that has a smaller width than the wavelength λ.

28. An optical apparatus comprising:
a light emitting device that emits an electromagnetic wave with a wavelength λ;
the optical device capable of controlling the electromagnetic wave according to claim 1; and
a mirror which is placed at an opposite side of the optical device to the light emitting device, and which reflects the electromagnetic wave toward the optical device.

29. An optical apparatus comprising:
the light emitting device according to claim 15; and
a phase difference element capable of converting the electromagnetic wave emitted by the light emitting device into a circular polarized light or an elliptical polarized light.

30. The optical apparatus according to claim 29, wherein the phase difference element is capable of converting the electromagnetic wave emitted by the light emitting device into a right circular polarized light or a right elliptical polarized light.

31. The optical apparatus according to claim 29, wherein the phase difference element is capable of converting the electromagnetic wave emitted by the light emitting device into a left circular polarized light or a left elliptical polarized light.

32. A production method of an optical device comprising a polarizer the method comprising:
a first phase difference element forming process to form the first phase difference element;
a protector forming process to form a protector that protects a concavo-convex structure of the first phase difference element; and
a polarizer forming process to form a polarizer which comprises a concavo-convex structure, allows a P polarized light of an incident electromagnetic wave to pass through, and reflects an S polarized light thereof, and the first phase difference element which comprises the concavo-convex structure, and which is capable of converting a linear polarized light into a circular polarized light or an elliptical polarized light.

33. A production method of an optical device comprising a polarizer, the method comprising:
a polarizer forming process to form a polarizer which comprises a concavo-convex structure, allows a P polarized light of an incident electromagnetic wave to pass through, and reflects an S polarized light thereof, and a first phase difference element which comprises a concavo-convex structure, and which is capable of converting a linear polarized light into a circular polarized light or an elliptical polarized light,
a protector forming process to form a protector that protects the concavo-convex structure of the polarizer; and
a first phase difference element forming process to form the first phase difference element.

34. A production method of an optical device comprising a polarizer the method comprising:
a first phase difference element forming process to form a first phase difference element;
a polarizer forming process to form a polarizer which comprises a concavo-convex structure, allows a P polarized light of an incident electromagnetic wave to pass through, and reflects an S polarized light thereof, and the first phase difference element which comprises a concavo-convex structure, and which is capable of converting a linear polarized light into a circular polarized light or an elliptical polarized light; and
a first joining process to join the first phase difference element and the polarizer together.

35. The optical device production method according to claim 32, further comprising:
a second phase difference element forming process to form a second phase difference element capable of converting a linear polarized light into a circular polarized light or an elliptical polarized light; and
a second joining process to join the second phase difference element and the polarizer together.
